(19) United States
(12) Patent Application Publication
(10) Pub. No.: US 2014/0366938 A1
(43) Pub. Date: Dec. 18, 2014

(54) WAFER SOLAR CELL AND SOLAR CELL PRODUCTION METHOD

(71) Applicant: HANWHA Q CELLS GMBH, Bitterfeld-Wolfen (DE)

(72) Inventors: Stefan BORDIHN, Leipzig (DE); Janko CIESLAK, Wolfen (DE); Verena MERTENS, Leipzig (DE); Florian STENZEL, Leipzig (DE)

(21) Appl. No.: 14/304,466

(22) Filed: Jun. 13, 2014

(30) Foreign Application Priority Data
Jun. 17, 2013 (DE) 102013106272.5

(51) Int. Cl. H01L 31/0224; H01L 31/0216; H01L 31/18

(52) U.S. Cl. CPC H01L 31/022458; H01L 31/1868; H01L 31/02167
USPC 136/256; 438/98

(57) ABSTRACT

A wafer solar cell comprising a semiconductor layer, a back-side emitter layer, a passivation layer arranged on the emitter layer, openings being formed in said passivation layer, and a metallization layer arranged on the passivation layer, wherein the emitter layer, the passivation layer and/or the metallization layer substantially completely covers a solar cell back side, and wherein adjacent to each opening a doping region is formed which extends into the emitter layer and/or into the semiconductor layer and is doped by means of a metal from the metallization layer and/or from the passivation layer. Furthermore, the invention relates to a solar cell production method for producing such a wafer solar cell.

### PRIORITY CLAIM

The present application claims priority to German Patent Application No. 10 2013 106 272.5, filed on Jun. 17, 2013, which said application is incorporated by reference in its entirety herein.

### FIELD OF THE INVENTION

The invention relates to a wafer solar cell and to a solar cell production method.

### BACKGROUND OF THE INVENTION

Wafer-based solar cells comprising back-side emitters, that is to say comprising an emitter layer arranged on the back side, that is to say on a surface of the solar cell facing away from the light, constitute an important alternative technology to customary solar cell structures, in which the emitter layer is arranged on the light incidence side. In particular, very efficient solar cells based on n-type semiconductor wafers can be produced with this technology. One possible realization of a back-side emitter layer consists in applying a suitable metal paste to the back-side surface of the semiconductor wafer and subsequently subjecting it to a firing step. As a result, metal elements from the metal paste penetrate into the semiconductor and produce a doped emitter layer on the semiconductor surface. A metallization layer contact-connected to the emitter layer is produced at the same time.

In order to increase the efficiency of the solar cell, it would be advantageous to provide a passivation layer on the emitter layer. However, the method described above is not suitable for producing such a structure. Instead, conventional practice involves producing a selective emitter structure by means of selective diffusion, a contact-connection by means of a silver-aluminium contact grid subsequently being carried out. This has the disadvantage, however, that the contact-connection has to be aligned on the emitter structure, which entails additional outlay and constitutes an additional fault source.

### SUMMARY OF THE INVENTION

It is an object of the invention to provide an efficient and cost-effective wafer-based solar cell comprising a back-side emitter and a reliable production method therefor.

The object is achieved according to the invention by means of a wafer solar cell and a solar cell production method. Advantageous developments of the invention are presented in the dependent claims.

The invention is based on the consideration of aligning with one another in a simple manner the doping regions which are required for making contact with the emitter layer and the openings in the passivation layer which are likewise required for making contact with the emitter layer. In this case, a type of self-alignment is used by virtue of the position of the openings in the passivation layer predefining the position of the doping regions. Two different production variants arise for this purpose: In a first variant, the openings in the passivation layer are formed in such a way that the doping regions arise at the same time, for example by means of laser doping, if the openings are produced by means of a laser. In a second variant, the openings are formed before the production of the doping in the passivation layer, and a subsequent metallization step is selected such that the doping regions arise at the same time in this case, to be precise on account of the preceding structuring of the passivation layer only in the openings. These two basic variants are found in a pure form, with modifications or in mixed forms in the particular embodiments described below.

The result of this procedure is that adjacent to each opening a doping region is formed which extends into the emitter layer and, if appropriate, also into the semiconductor layer and that the doping is formed by means of a metal from the metallization layer and/or from the passivation layer. That means, in particular, that a metal which is present in a chemical compound or an alloy in the metallization layer and/or in the passivation layer is present as a dopant in the doping region.

Adjacent to each opening means in this case that the doping region or doping regions adjoins or adjoin a respective opening, that is to say, in a plan view of the solar cell back side, is or are present within the opening or in direct proximity around the opening.

One advantage of this method is that the emitter layer or the metallization layer or in particular both layers can be produced over the whole area despite an intervening passivation layer, without an additional alignment between the emitter and the metallization being necessitated. The fact that the emitter layer, the passivation layer and/or the metallization layer substantially completely cover the solar cell back side means that one, two or three of these layers are arranged over the whole area on the solar cell back side. Cut-outs can be provided only at said openings, in edge regions and/or in other production-dictated regions.

The openings in the passivation layer can be punctiform or linear. Punctiform openings can have diameters of the order of magnitude of from a few tens of micrometres (μm) to a few hundred μm. Linear openings can have line thicknesses of approximately 10 μm to a few hundred μm.

In one preferred embodiment it is provided that the openings extend in or through the emitter layer and/or through the metallization layer. That means that the openings can extend as recesses partly into the emitter layer, or they can penetrate as holes through the emitter layer. If the openings form holes in the emitter layer, then they can additionally partly extend into the semiconductor layer.

In one advantageous development it is provided that the metallization layer fills the openings in the passivation layer. That means that the metallization layer projects into the openings. This occurs particularly if the openings are produced before the metallization layer is applied or deposited, for example if, after the openings have been produced, a metal paste is applied to the solar cell back side and this also penetrates into the openings.

In accordance with one expedient configuration it is provided that the semiconductor layer is formed from an n-type semiconductor, in particular from an n-type silicon. In this case, the emitter layer is preferably formed as a p-type emitter. Accordingly, the doping regions are preferably a more highly doped p-type region, which is usually referred to as p⁺-type or p⁺⁺-type region.

In one expedient embodiment it is provided that the metallization layer contains aluminium. A metallization layer produced by means of an aluminium-containing paste can therefore be involved. On the other hand, the metallization layer can also be deposited as an aluminium layer or aluminium-containing layer, in particular by means of a vapor deposition method. In the case of an aluminium-containing metallization layer, the doping of the doping region can stem from the aluminium from the metallization layer or from the metal paste. An aluminium-containing paste has the advantage over a silver-containing paste that it does not attack the passivation layer or attacks it only to a small extent during a firing step described below. Moreover, a p-type doping can be obtained with aluminium, which is particularly beneficial in the case of n-type semiconductor layers.

The wafer solar cell described here comprises a back-side emitter layer on its semiconductor layer. That means that the emitter layer is formed on that side of the semiconductor layer which faces away from the light during use of the solar cell, that is to say on the solar cell back side. In this case, the emitter layer can be applied as an additional layer on the back side of the semiconductor layer. It is rather more preferable, however, for the emitter layer to be formed as a doping layer in the semiconductor layer. This solar cell back side and the layers and structures arranged thereon are principally described in the present case. On the solar cell front side, the solar cell can be prepared in any suitable way, for example with a front surface field (FSF), with an antireflection layer, contact fingers or contact grids applied on the front side and/or a front-side passivation layer.

It is preferably provided that the doping region has a higher doping than the emitter layer. That means that the density of the majority charge carriers at a specific temperature is higher in the doping regions than in the emitter layer.

In order to produce the wafer solar cell described here, firstly a semiconductor wafer having a semiconductor layer is provided. An emitter layer is produced on or in said semiconductor layer, to be precise on the solar cell back side of the semiconductor wafer facing away from the light incidence side in the finished solar cell. A passivation layer is then deposited onto the emitter layer, said passivation layer providing for a surface passivation. For this purpose, the passivation layer is formed from a suitable dielectric material, for example from silicon oxide, silicon nitride, silicon oxynitride, aluminium oxide, aluminium oxynitride or the like.

In the course of the method, a metallization layer is additionally produced on the passivation layer. In this case, the metallization layer can be produced by means of a deposition method, for example by means of vapor deposition (PVD, physical vapor deposition). Advantageously, however, it can be provided that producing the metallization layer on the passivation layer comprises applying a metal paste to the passivation layer and heating the semiconductor wafer and the applied metal paste in order to produce a metallization layer. In this method, known as paste metallization, the metal paste can be applied to the passivation layer by means of a screen printing method, for example.

In addition, openings are produced in the passivation layer. At the same time as the production of the openings or in a later method step, a doping region is produced adjacent to each opening in such a way that the doping region extends into the emitter layer and/or into the semiconductor layer and is doped by means of a metal from the metallization layer and/or from the passivation layer.

In one advantageous configuration it is provided that producing the openings in the passivation layer is carried out before producing the metallization layer. In this case, the openings are formed in the passivation layer, without a metallization layer covering the passivation layer. If the openings are produced by means of the introduction of energy, for example by means of a laser, then said energy can simultaneously drive material from the passivation layer, in particular the metal from the passivation layer, into the emitter layer and/or the semiconductor layer and thus produce the doping regions. In a subsequent step, the metallization layer can then be produced, which necessarily also penetrates into the openings and preferably fills them. If the metallization layer is produced by means of a thermal treatment, for example by a metal paste being applied and a firing step subsequently being carried out, then the doping regions can be produced on the basis of the thermal treatment, namely by dopants from the metal paste passing into the emitter layer and/or into the semiconductor layer.

In accordance with one preferred development it is provided that producing the openings in the passivation layer is carried out after producing the metallization layer and at the same time as producing the doping region. If the openings are produced by means of the introduction of energy, for example by means of a laser, then said energy can simultaneously drive material from the passivation layer and/or from the metallization layer, in particular the metal from the metallization layer, into the emitter layer and/or the semiconductor layer and thus produce the doping regions.

In accordance with one preferred configuration of the production method for the case where the metallization layer is implemented by means of paste metallization, it is provided that producing the openings in the passivation layer is carried out after applying the metal paste to the passivation layer. In this case, the openings can be implemented still before the firing step described below, that is to say still while the metal is present in the form of the metal paste on the solar cell back side.

Preferably, when carrying out a paste metallization, it is provided that heating the semiconductor wafer and the applied metal paste in order to produce the metallization layer is carried out in a two-step method, wherein, during a first heating step, the applied metal paste is dried at a temperature of between 150° C. and 500° C. and, during a subsequent second heating step, the dried metal paste is fired at a temperature of between 700° C. and 1000° C. If openings have not yet been formed in the passivation layer, then although the firing step has the effect that the metal layer thus produced adheres well to the passivation layer, still no electrical contact is produced between the metal layer and the emitter layer. This must then be redressed in a subsequent step in which the openings are produced at the same time.

The openings in the passivation layer can be produced by any method suitable for this purpose, in particular by a method in which energy is introduced into the passivation layer and into the surrounding structures and layers. In one expedient development it is provided that the openings in the passivation layer are produced by means of laser irradiation. In this case, the laser irradiation can simultaneously have the effect that the metal from the passivation layer and/or from the metallization layer penetrates into the emitter layer and/or the semiconductor layer in order to form the doping regions. In other words, a laser doping is then involved.

The invention is explained below on the basis of exemplary embodiments with reference to the figures, in which:

### BRIEF DESCRIPTION OF THE DRAWINGS

FIGS. 1A to 1E show the step by step production of a wafer solar cell in accordance with one embodiment; and

FIGS. 2A to 2E show the step by step production of a wafer solar cell in accordance with a further embodiment.

### DETAILED DESCRIPTION

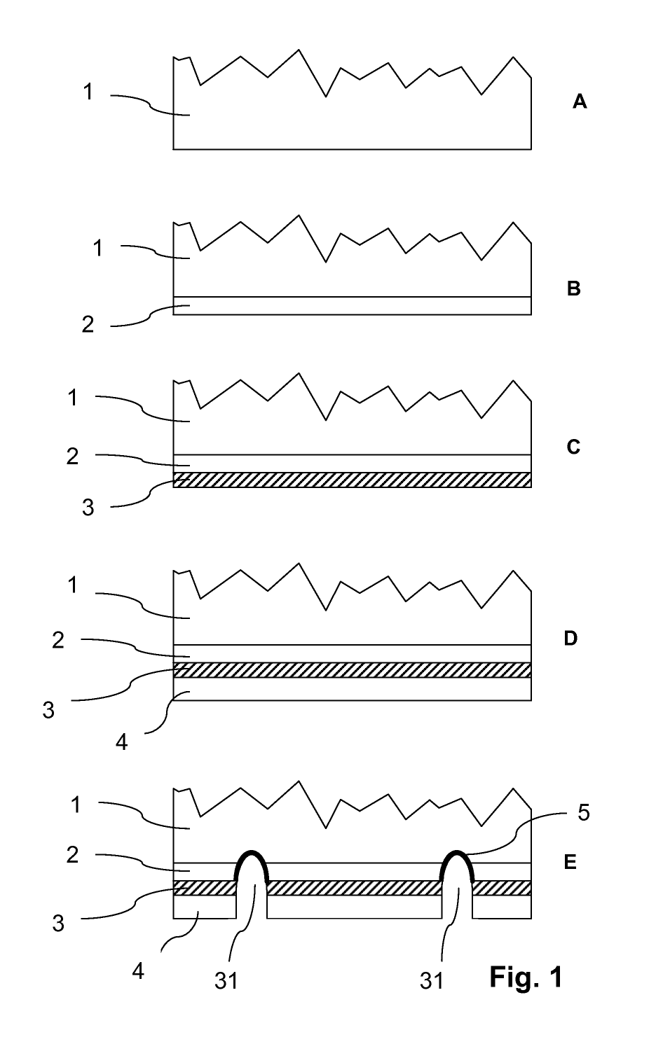

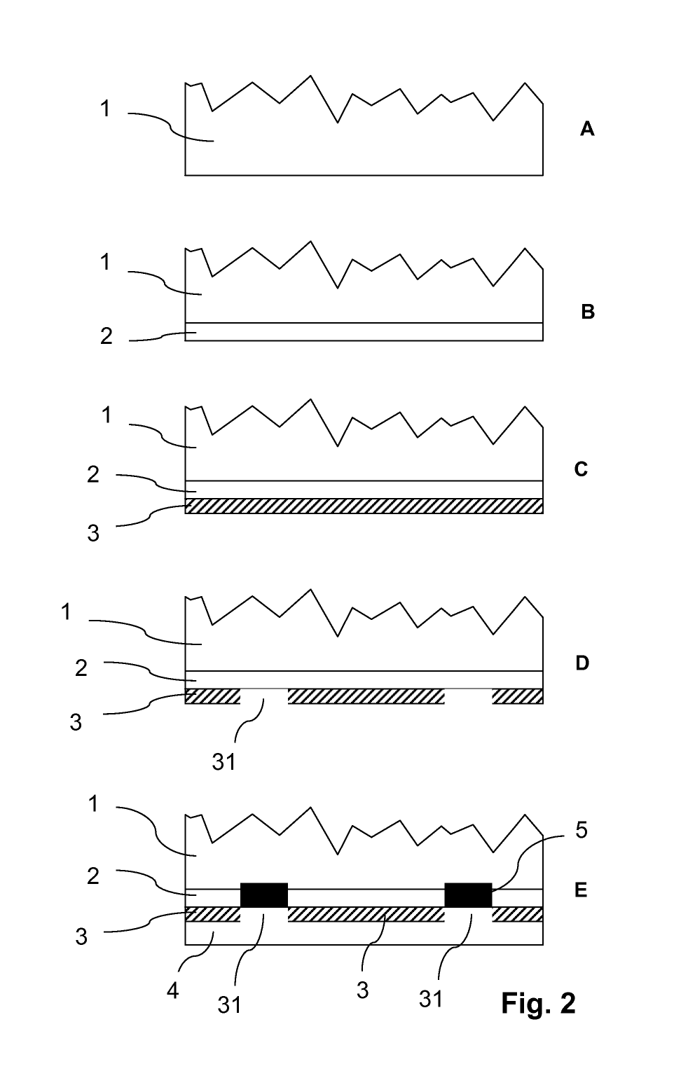

FIG. 1 shows a sequence of intermediate products during the production of a wafer solar cell in accordance with one particular embodiment in which the openings in the passivation layer are produced after the metallization layer has been produced. As in FIG. 2, only the solar cell back side, that is to say the solar cell side which functions as the side facing away from the light in the finished solar cell, is considered here. The jagged line in the illustrations therefore does not represent the solar cell front side or solar cell light incidence side, but rather is intended precisely to illustrate that the solar cell front side is not considered here and can have any suitable form or any suitable layer sequence.

As illustrated in FIG. 1A, firstly a semiconductor layer 1 in the form of a semiconductor wafer is provided. As shown in FIG. 1B, an emitter layer 2 is produced on said semiconductor layer 1 on the back side, either by means of the deposition of a suitable semiconductor material or by means of the doping of the semiconductor layer 1 on its back side. As illustrated in FIG. 1C, a passivation layer 3 is deposited onto the emitter layer 2, said passivation layer providing for a surface passivation. Finally, a metallization layer 4, as illustrated in FIG. 1D, is produced on the passivation layer.

In order subsequently to produce an electrical connection between the metallization layer 4 and the emitter layer 2, openings 31 are produced in the passivation layer 3 by means of laser ablation, said openings in the present case also extending through the emitter layer 2 and even extending partly as recesses into the semiconductor layer 1. On account of the energy introduced by the laser, elements from the metallization layer 4 and/or from the passivation layer 3, in particular a metal contained in these layers, are additionally driven into emitter layer 2 and into the semiconductor layer 1, where they produce doping regions 5 in direct proximity to the openings 31. Consequently, the laser serves not only for opening the passivation layer 3, but also for producing the doping regions 5 by means of laser doping.

A modified method for producing an electrical connection between a back-side emitter layer 2 and a metallization layer 4 is illustrated with reference to the pictorial sequence illustrated in FIGS. 2A to 2E. In this case, the method steps in accordance with FIGS. 2A, 2B and 2C up to the deposition of the passivation layer 3 correspond to the method steps illustrated in FIGS. 1A, 1B and 1C. In accordance with FIG. 2D, however, before a metallization layer 4 is produced, the openings 31 are then produced in the passivation layer 3, preferably by means of laser irradiation.

It is only in a subsequent step that the metallization layer 4 is formed on the passivation layer 3, such that the metallization layer 4 also extends into the openings 31. Either during the production of the passivation layer 4, in particular during the firing step when using a paste metallization, or after the production of the metallization layer 4, for example likewise by means of laser doping, the doping regions 5 are produced below the openings 31 in the emitter layer 2. As illustrated in FIG. 2E, here as well the doping regions 5 extend partly into the semiconductor layer 1. Unlike the case illustrated in FIG. 1E, however, the openings 31 do not extend into the emitter layer 2, which is dependent, however, on the individual process parameters such as laser power, irradiation duration and the like.

### LIST OF REFERENCE SIGNS

1 Semiconductor layer
2 Emitter layer
3 Passivation layer
31 Opening in the passivation layer
4 Metallization layer
5 Doping region

What is claimed is:

1. A wafer solar cell, comprising:
a semiconductor layer, a back-side emitter layer, a passivation layer arranged on the emitter layer, openings being formed in said passivation layer, and a metallization layer arranged on the passivation layer, wherein the emitter layer, the passivation layer and/or the metallization layer substantially completely covers a solar cell back side, and wherein adjacent to each opening a doping region is formed which extends into the emitter layer and/or into the semiconductor layer and is doped by means of a metal from the metallization layer and/or from the passivation layer.

2. The wafer solar cell according to claim 1, wherein the openings extend in or through the emitter layer and/or through the metallization.

3. The wafer solar cell according to claim 1, wherein the metallization layer fills the openings in the passivation layer.

4. The wafer solar cell according to claim 1, wherein the semiconductor layer is formed from an n-type semiconductor.

5. The wafer solar cell according to claim 1, wherein the metallization layer contains aluminium.

6. The wafer solar cell according to claim 1, wherein the emitter layer is formed as a doping layer in the semiconductor layer.

7. The wafer solar cell according to claim 6, wherein doping region has a higher doping than the emitter layer.

8. A solar cell production method comprising the following method steps:
providing a semiconductor wafer having a semiconductor layer;
producing an emitter layer on a solar cell back side of the semiconductor wafer facing away from the light incidence side in the finished solar cell;
depositing a passivation layer on the emitter layer;
producing a metallization layer on the passivation layer;
producing openings in the passivation layer; and
producing a doping region adjacent to each opening in such a way that the doping region extends into the emitter layer and/or into the semiconductor layer and is doped by means of a metal from the metallization layer and/or from the passivation layer.

9. The solar cell production method according to claim 8, wherein producing the openings in the passivation layer is carried out before producing the metallization layer.

10. The solar cell production method according to claim 8, wherein producing the openings in the passivation layer is carried out after producing the metallization layer and at the same time as producing the doping region.

11. The solar cell production method according to claim 8, wherein producing the metallization layer on the passivation layer comprises applying a metal paste to the passivation layer and heating the semiconductor wafer and the applied metal paste in order to produce a metallization layer.

12. The solar cell production method according to claim 11, wherein producing the openings in the passivation layer is carried out after applying the metal paste to the passivation layer.

13. The solar cell production method according to claim 11, wherein heating the semiconductor wafer and the applied metal paste in order to produce the metallization layer is carried out in a two-step method, wherein, during a first heating step, the applied metal paste is dried at a temperature of between 150° C. and 500° C. and, during a subsequent second heating step, the dried metal paste is fired at a temperature of between 700° C. and 1000° C.

14. The solar cell production method according to claim 8, wherein the openings in the passivation layer are produced using laser irradiation.
